(19) United States
(12) Patent Application Publication
(10) Pub. No.: US 2025/0277823 A1
(43) Pub. Date: Sep. 4, 2025

(54) CURRENT SENSOR AND CONTROL METHOD THEREOF

(71) Applicants: Guangdong Power Grid Co., Ltd., Guangzhou (CN); Heyuan Power Supply Bureau Of Guangdong Power Grid Corporation, Heyuan (CN)

(72) Inventors: Kai SHANG, Heyuan (CN); Liuhui YANG, Heyuan (CN); Haobin HONG, Heyuan (CN); Shuhao ZHONG, Heyuan (CN); Hongnan ZHANG, Heyuan (CN); Yanfu HUANG, Heyuan (CN); Ning HUANG, Heyuan (CN); Zhixiong WEI, Heyuan (CN); Rui YAO, Heyuan (CN); Li SUN, Heyuan (CN); Xiaobo CHEN, Heyuan (CN); Liang SONG, Heyuan (CN); Zhixiong HUANG, Heyuan (CN); Xiaojun ZHANG, Heyuan (CN); Jingfang YOU, Heyuan (CN)

(21) Appl. No.: 19/002,609

(22) Filed: Dec. 26, 2024

(30) Foreign Application Priority Data
Mar. 1, 2024 (CN) 202410233574.7

(51) Int. Cl. G01R 15/18; G01R 19/15; G01R 19/25

(52) U.S. Cl. CPC G01R 15/185; G01R 19/15; G01R 19/2506

(57) ABSTRACT

Provided are a current sensor and a control method thereof. The current sensor includes a main core and an auxiliary core; a primary winding disposed on the main core and the auxiliary core; a secondary winding disposed on the main core and the auxiliary core; a compensation winding disposed on the auxiliary core; a detection winding disposed on the main core; and a compensation circuit configured to acquire an alternating current (AC) signal induced by the detection winding and apply a current signal to the compensation winding based on the AC signal to make the compensation winding generate a reverse excitation electromotive force to reduce an excitation current in the current sensor.

### CROSS-REFERENCE TO RELATED APPLICATION

This application claims priority to Chinese patent application No. 202410233574.7 filed with the China National Intellectual Property Administration (CNIPA) on Mar. 1, 2024, the disclosure of which is incorporated herein by reference in its entirety.

### TECHNICAL FIELD

The present disclosure relates to the field of sensor technology, particularly a current sensor and a control method thereof.

### BACKGROUND

A sensor is a detection device that senses the information being measured and convert that information into an electrical signal or other desired forms according to certain rules to satisfy the requirements for transmission, processing, storage, display, recording, and control of information. Generally, a sensor may only detect a specific type of information. A lightning arrester, also known as a surge protector or an overvoltage limiter, is a key device that ensures the safe and stable operation of power grid systems. The most commonly used type of lightning arrester in current power grid systems is a zinc oxide lightning arrester that may leverage its nonlinear volt-ampere characteristics to significantly reduce overvoltage entering the grid to ensure the stable operation of electrical equipment.

Currently, existing lightning arresters are able to monitor only one parameter: wide-range lightning strike current before converting it into an electrical signal and outputting the signal. When multiple signal parameters are required to be monitored, multiple sensors are required to be connected. However, connecting multiple sensors to the lightning arrester increases the size, weight, and power consumption of the lightning arrester, leading to greater measurement errors and lower accuracy.

### SUMMARY

The present disclosure provides a current sensor and a control method thereof to achieve the capability of detecting multiple signal parameters simultaneously, reducing the margin of error, and improving the measurement accuracy.

The present disclosure provides a current sensor. The current sensor includes a main core and an auxiliary core; a primary winding disposed on the main core and the auxiliary core; a secondary winding disposed on the main core and the auxiliary core; a compensation winding disposed on the auxiliary core; a detection winding disposed on the main core; and a compensation circuit configured to acquire an alternating current (AC) signal induced by the detection winding and apply a current signal to the compensation winding based on the AC signal to make the compensation winding generate a reverse excitation electromotive force to reduce an excitation current in the current sensor.

In some embodiments, the primary winding passes through the middle of the main core and the middle of the auxiliary core in a through-core connection, and the secondary winding is wound around the main core and the auxiliary core.

In some embodiments, the compensation circuit is configured to reduce the excitation current to less than a preset value.

In some embodiments, the magnitude of an induced potential in the compensation winding reflects the magnitude of the excitation current; and the compensation circuit is configured to determine a magnetic flux in the main core based on the magnitude of a voltage signal of the compensation winding to control the magnitude of an output compensation current.

In some embodiments, the compensation circuit includes a preamplifier circuit, a phase shift circuit, and a compensation current generation circuit.

The input of the preamplifier circuit is connected to the detection winding. The input of the phase shift circuit is connected to the output of the preamplifier circuit. The compensation current generation circuit is connected to the output of the phase shift circuit and connected to the compensation winding.

The preamplifier circuit is configured to perform preamplification of the induced AC signal.

The phase shift circuit is configured to perform phase-shifting processing on the AC signal and send the phase-shifted amplified AC signal to the compensation current generation circuit.

The compensation current generation circuit is configured to generate a compensation current and output the compensation current to the compensation winding to make the compensation winding generate the reverse excitation electromotive force.

In some embodiments, the compensation circuit also includes a secondary amplification circuit, a filter circuit, a microcontroller, and a digital potentiometer.

The input of the secondary amplification circuit is connected to the output of the preamplifier circuit.

The input of the filter circuit is connected to the output of the secondary amplification circuit.

The microcontroller is connected to the output of the filter circuit. The digital potentiometer is connected between the microcontroller and the compensation current generation circuit.

The microcontroller is configured to control the magnitude of the compensation current by controlling the resistance value of the digital potentiometer.

In some embodiments, the current sensor also includes a first clipping protection circuit and a second clipping protection circuit.

The first clipping protection circuit is connected between the detection winding and the preamplifier circuit.

The second clipping protection circuit is connected between the compensation current generation circuit and the compensation winding. The first clipping protection circuit and the second clipping protection circuit are configured for current surge protection.

In some embodiments, the current sensor also includes a secondary load connected to the secondary winding. Energy required by the secondary load is supplied by the auxiliary core, and zero magnetic flux is reached in the main core.

The present disclosure further provides a control method of a current sensor.

The current sensor includes a main core and an auxiliary core; a primary winding disposed on the main core and the auxiliary core; a secondary winding disposed on the main core and the auxiliary core; a compensation winding disposed on the auxiliary core; and a detection winding disposed on the main core.

The control method includes acquiring an alternating current (AC) signal induced by the detection winding and applying a current signal to the compensation winding based on the AC signal to make the compensation winding generate a reverse excitation electromotive force to reduce an excitation current in the current sensor.

In some embodiments, the current sensor also includes a compensation circuit. The compensation circuit includes a preamplifier circuit in a through-core connection, a phase shift circuit, and a compensation current generation circuit.

The input of the preamplifier circuit is connected to the detection winding. The input of the phase shift circuit is connected to the output of the preamplifier circuit. The compensation current generation circuit is connected to the output of the phase shift circuit and connected to the compensation winding.

The preamplifier circuit is configured to perform preamplification of the induced AC signal.

The phase shift circuit is configured to perform phase-shifting processing on the AC signal and send the phase-shifted amplified AC signal to the compensation current generation circuit.

The compensation current generation circuit is configured to generate a compensation current and output the compensation current to the compensation winding to make the compensation winding generate the reverse excitation electromotive force.

The compensation circuit also includes a secondary amplification circuit, a filter circuit, a microcontroller, and a digital potentiometer.

The input of the secondary amplification circuit is connected to the output of the preamplifier circuit.

The input of the filter circuit is connected to the output of the secondary amplification circuit.

The microcontroller is connected to the output of the filter circuit. The digital potentiometer is connected between the microcontroller and the compensation current generation circuit.

The control method includes that the microcontroller controls the magnitude of the compensation current by controlling the resistance value of the digital potentiometer.

It is to be understood that the content described in this part is neither intended to identify key or important features of embodiments of the present disclosure nor intended to limit the scope of the present disclosure. Other features of the present disclosure are apparent from the description provided hereinafter.

### BRIEF DESCRIPTION OF DRAWINGS

To illustrate solutions of embodiments of the present disclosure more clearly, drawings used in description of embodiments of the present disclosure are described hereinafter. Apparently, these drawings illustrate part of embodiments of the present disclosure. Those of ordinary skill in the art may obtain other drawings based on these drawings on the premise that no creative work is done.

FIG. 1 is a diagram of a bipolar zero-flux current transformer according to an embodiment of the present disclosure.

FIG. 2 is a diagram of a current sensor according to an embodiment of the present disclosure.

FIG. 3 is a diagram of a hardware circuit design of a current sensor according to an embodiment of the present disclosure.

FIG. 4 is a flowchart of a control method of a current sensor according to an embodiment of the present disclosure.

### DETAILED DESCRIPTION

For a better understanding of solutions of the present disclosure by those skilled in the art, solutions in embodiments of the present disclosure are described clearly and completely hereinafter in conjunction with the drawings in embodiments of the present disclosure. Apparently, the embodiments described hereinafter are part, not all, of embodiments of the present disclosure. Based on embodiments of the present disclosure, all other embodiments obtained by those of ordinary skill in the art on the premise that no creative work is done are within the scope of the present disclosure.

It is to be noted that terms such as “first” and “second” in the description, claims and drawings of the present disclosure are used to distinguish between similar objects and are not necessarily used to describe a particular order or sequence. It is to be understood that the data used in this way is interchangeable where appropriate so that embodiments of the present disclosure described herein may also be implemented in a sequence not illustrated or described herein. Additionally, terms “include” and “have” and any variations thereof are intended to encompass a non-exclusive inclusion. For example, a process, method, system, product or device that includes a series of steps or units not only includes the expressly listed steps or units but may also include other steps or units that are not expressly listed or are inherent to such process, method, product or device.

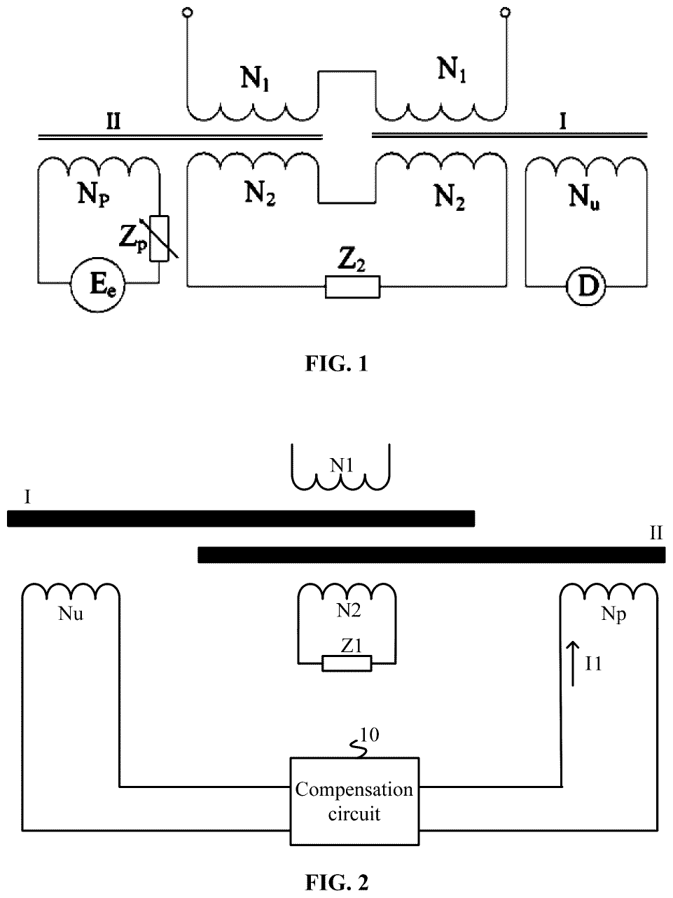

FIG. 1 is a diagram of a bipolar zero-flux current transformer according to an embodiment of the present disclosure. The current sensor of this embodiment of the present disclosure uses the principle of a bipolar zero-flux current transformer. As shown in FIG. 1, this bipolar zero-flux current transformer includes a main core I, an auxiliary core II, a primary winding N1, a secondary winding N2, a compensation winding Np, a detection winding Nu, a secondary load impedance Z2, an external adjustable impedance Zp, an applied compensation voltage Ee, and a measuring instrument D. The measuring instrument D refers to a zero instrument. Cores are common among electronic components. A core is used to generate a magnetic field in a circuit, facilitating a conversion between electrical energy and magnetic energy. The main core I and the auxiliary core II are the same in both the magnetic characteristic and the size. The primary winding N1 is the input signal connection terminal, generally connected to the power supply to receive energy from the power supply. The secondary winding N2 is typically connected to a load to primarily supply energy to the load. Both the primary winding N1 and secondary winding N2 are wound around the main core I and auxiliary core II. The main core I and the auxiliary core II are the same in both the magnetic characteristic and the size. In the absence of the compensation winding Np, the magnetic characteristic of the main core I and the magnetic characteristic of the auxiliary core II would be identical, and the energy required by the load would be supplied equally by the magnetic winding of the main core I and the magnetic winding of the auxiliary core II. However, if an external compensation voltage Ee is connected in series in the compensation circuit, the compensation winding Np generates a compensation current so that the magnetic potential of the auxiliary core II is rebalanced, and the energy required by the load is jointly provided by the main core I and the auxiliary core II, so that the magnetic operating points in the cores change. After the external adjustable impedance Zp is adjusted, the energy required by the load may be entirely supplied by the auxiliary core II, that is, the magnetic flux density in the auxiliary core II is very high, thereby achieving a zero magnetic flux in the main core I, and implementing high-precision measurement of the current sensor. The bipolar zero-flux current transformer requires an electromotive force that capable of being dynamically and linearly compensated on the auxiliary core II. Since errors in the bipolar zero-flux current transformer primarily arise from an excitation current, the core of the bipolar zero-flux current transformer is in a zero-flux state when the excitation current is zero.

FIG. 2 is a diagram of a current sensor according to an embodiment of the present disclosure. The current sensor designed by the present disclosure reduces a magnetic flux in a core to approximately zero, eliminating the influence of an excitation current on measurement. As shown in FIG. 2, the current sensor includes a main core I and an auxiliary core II; a primary winding N1 disposed on the main core I and the auxiliary core II; a secondary winding N2 disposed on the main core I and the auxiliary core II; a compensation winding Np disposed on the auxiliary core II; a detection winding Nu disposed on the main core I; and a compensation circuit 10 configured to acquire an alternating current (AC) signal induced by the detection winding Nu and apply a current signal to the compensation winding Np based on the AC signal to make the compensation winding Np generate a reverse excitation electromotive force to reduce an excitation current in the current sensor.

In the embodiment of the present disclosure, by way of example, the main core I and auxiliary core II are each a Permalloy core. Permalloy is an iron-nickel alloy with a high permeability in weak magnetic fields. Permalloy has a very high permeability under low magnetic field conditions. The excitation electromotive force is potential of a magnetic flux produced by a current flowing through a conductor, and is a quantity used to measure the magnetic field or electromagnetic field. The excitation current generally refers to an excitation inrush current that is influenced by an excitation voltage and is generated due to the magnetic saturation of the core. The primary winding N1 is disposed on the main core I and the auxiliary core II. The secondary winding N2 is disposed on the main core I and the auxiliary core II. The compensation winding Np is disposed on the auxiliary core II. In the absence of the compensation winding Np, the magnetic characteristic of the main core I and the magnetic characteristic of the auxiliary core II would be identical, and the energy required by the load would be supplied equally by the magnetic winding of the main core I and the magnetic winding of the auxiliary core II. In the presence of the compensation winding Np, the compensation winding Np is configured to generate a compensation current I1 so that the magnetic potential of the auxiliary core II is rebalanced, and the energy required by the load is jointly provided by the main core I and the auxiliary core II, so that the magnetic operating points in the cores change. The detection winding Nu is disposed on the main core I and configured to measure the magnetic flux density in the auxiliary core II. The magnitude of the induced potential reflects the magnitude of the excitation current. The detection winding Nu is also configured to provide a feedback voltage signal for the compensation winding Np. The compensation circuit 10 determines the magnetic flux in the core by acquiring the voltage signal induced by the detection winding Nu and applies a current signal to the compensation winding Np to make the compensation winding Np generate a reverse excitation electromotive force using the compensation winding Np, thereby reducing the excitation current in the current sensor to a very low level, reducing the error, and improving the measurement accuracy.

According to the solution of embodiments of the present disclosure, the current sensor includes a main core and an auxiliary core; a primary winding disposed on the main core and the auxiliary core; a secondary winding disposed on the main core and the auxiliary core; and a compensation winding disposed on the auxiliary core. In the absence of the compensation winding, the magnetic characteristic of the main core and the magnetic characteristic of the auxiliary core would be identical, and the energy required by the load would be supplied equally by the magnetic winding of the main core and the magnetic winding of the auxiliary core. In the presence of the compensation winding, the compensation winding is configured to generate a compensation current I1 so that the magnetic potential of the auxiliary core is rebalanced, and the energy required by the load is jointly provided by the main core and the auxiliary core, so that the magnetic operating points in the cores change. The current sensor also includes a detection winding. The detection winding is disposed on the main core and configured to measure the magnetic flux density in the auxiliary core. The magnitude of the induced potential reflects the magnitude of the excitation current. The detection winding is also configured to provide a feedback voltage signal for the compensation winding. The compensation circuit is configured to determine the magnetic flux in the core by acquiring the voltage signal induced by the detection winding and apply a current signal to the compensation winding to make the compensation winding generate a reverse excitation electromotive force using the compensation winding, thereby reducing the excitation current in the current sensor to an extremely low level, achieving a wide measurement bandwidth, enabling the measurement of multiple signal quantities, reducing the error, and improving the measurement accuracy.

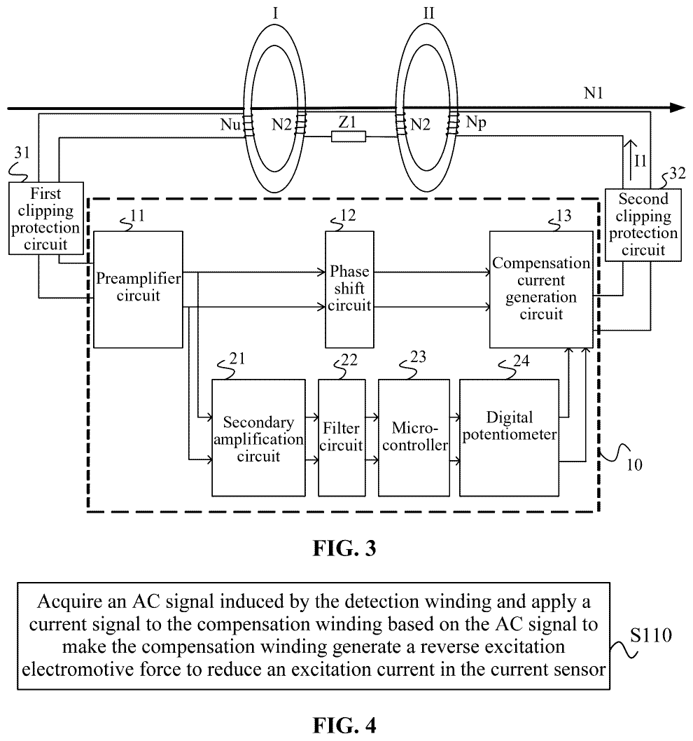

FIG. 3 is a diagram of a hardware circuit design of a current sensor according to an embodiment of the present disclosure. As shown in FIG. 3, the primary winding N1 passes through the middle of the main core I and the middle of the auxiliary core II in a through-core connection, and the secondary winding N2 is wound around the main core I and auxiliary core II.

Based on the solution of the previous embodiment of the present disclosure, referring to FIG. 3, the compensation circuit 10 is configured to reduce the excitation current to less than a preset value.

In the embodiment of the present disclosure, the preset value is a preset numerical value representing the magnitude of the excitation current. For example, the preset value is 0.1 A. The function of the compensation circuit 10 in the current sensor is to reduce the excitation current to less than 0.1 A, ideally to zero.

Based on the solution of the previous embodiment of the present disclosure, referring to FIG. 3, the magnitude of an induced potential in the compensation winding Np reflects the magnitude of the excitation current; and the compensation circuit 10 is configured to determine a magnetic flux in the main core I based on the magnitude of a voltage signal of the compensation winding Np to control the magnitude of an output compensation current I1.

In the embodiment of the present disclosure, the electromotive force generated in electromagnetic induction is referred to as the induced potential. The magnitude of the induced potential in the compensation winding Np reflects the magnitude of the excitation current. By way of example, when the induced potential is large, it is indicated that the excitation current in the compensation circuit is also large. The magnitude of the voltage signal of the compensation winding Np reflects the magnetic flux in the main core I. When the voltage signal of the compensation winding Np is large, it is indicated that the magnetic flux in the main core I is also large. Therefore, it is necessary to control the magnitude of the output compensation current I1 to reduce the compensation current I1 to make the compensation winding Np generate a greater reverse excitation electromotive force, thereby reducing the excitation current close to zero.

Based on the solution of the previous embodiment of the present disclosure, referring to FIG. 3, the compensation circuit 10 includes a preamplifier circuit 11, a phase shift circuit 12, and a compensation current generation circuit 13. The input of the preamplifier circuit 11 is connected to the detection winding Nu. The input of the phase shift circuit 12 is connected to the output of the preamplifier circuit 11. The compensation current generation circuit 13 is connected to the output of the phase shift circuit 12 and connected to the compensation winding Np. The preamplifier circuit 11 is configured to perform preamplification the induced AC signal. The phase shift circuit 12 is configured to perform phase-shifting processing on an amplified voltage signal and send the phase-shifted amplified voltage signal to the compensation current generation circuit 13. The compensation current generation circuit 13 is configured to generate a compensation current and output the compensation current to the compensation winding Np to make the compensation winding Np generate the reverse excitation electromotive force.

The preamplifier circuit 11 is disposed between a signal source and an amplifier and configured to receive a voltage signal from the signal source. In the embodiment of the present disclosure, the preamplifier circuit 11 is configured to perform preamplification of the AC voltage signal induced by the detection winding Nu in the main core I. The amplified AC voltage signal is processed by the phase shift circuit 12 and then sent to the compensation current generation circuit 13. The phase shift circuit 12 is configured to change the phase of a signal and typically consists of a ray-type oscillator, an amplifier, and a filter. The compensation current generation circuit 13 is configured to generate a compensation current I1 and output the compensation current I1 to the compensation winding Np to make the compensation winding Np generate the reverse excitation electromotive force, thereby reducing the excitation current to a very low level. The compensation current generation circuit 13 may be a controllable current source.

Based on the solution of the previous embodiment of the present disclosure, referring to FIG. 3, the compensation circuit 10 also includes a secondary amplification circuit 21, a filter circuit 22, a microcontroller 23, and a digital potentiometer 24. The input of the secondary amplification circuit 21 is connected to the output of the preamplifier circuit 11. The input of the filter circuit 22 is connected to the output of the secondary amplification circuit 21. The microcontroller 23 is connected to the output of the filter circuit 22. The digital potentiometer 24 is connected between the microcontroller 23 and the compensation current generation circuit 13. The microcontroller 23 is configured to control the magnitude of the compensation current I1 by controlling the resistance value of the digital potentiometer 24.

In the embodiment of the present disclosure, the filter circuit 22 is configured to filter out a ripple from the rectified output voltage and is typically composed of reactive components. The digital potentiometer 24, also known as a digitally controlled programmable resistor, is a new type of complementary metal-oxide-semiconductor (CMOS) digital-analog mixed signal processing integrated circuit that replaces a traditional analog potentiometer. The digital potentiometer 24 is controlled by digital input to produce an analog output. The microcontroller 23 is configured to control the magnitude of the compensation current I1 by controlling the resistance value of the digital potentiometer 24. By way of example, when a larger compensation current I1 is required, the microcontroller 23 adjusts the resistance value of the digital potentiometer 24 to decrease the resistance value of the digital potentiometer 24, thereby increasing the compensation current I1.

Based on the solution of the previous embodiment of the present disclosure, referring to FIG. 3, the current sensor also includes a first clipping protection circuit 31 and a second clipping protection circuit 32. The first clipping protection circuit 31 is connected between the detection winding Nu and the preamplifier circuit 11. The second clipping protection circuit 32 is connected between the compensation current generation circuit 13 and the compensation winding Np. The first clipping protection circuit 31 and the second clipping protection circuit 32 are configured for current surge protection.

In the embodiment of the present disclosure, the first clipping protection circuit 31 and the second clipping protection circuit 32 are added to ensure that the current sensor can protect coils and subsequent circuits from damage when subjected to a large current shock.

Based on the solution of the previous embodiment of the present disclosure, referring to FIG. 2, the current sensor also includes a secondary load Z1 connected to the secondary winding N2. Energy required by the secondary load Z1 is supplied by the auxiliary core II, and zero magnetic flux is reached in the main core I.

In the embodiment of the present disclosure, the secondary load Z1 is connected to the secondary winding N2, and energy required by the secondary load Z1 is supplied by the auxiliary core II, resulting in a high magnetic flux density in the auxiliary core II and thus a zero magnetic flux in the main core I.

According to the solution of the embodiment of the present disclosure, in the current sensor, the primary winding passes through the middle of the main core and the middle of the auxiliary core in a through-core connection, the secondary winding is wound around the main core and the auxiliary core, and the compensation circuit is configured to determine a magnetic flux in the main core based on the magnitude of a voltage signal of the compensation winding to control the magnitude of an output compensation current to make the compensation winding generate a greater reverse excitation electromotive force to reduce an excitation current in the current sensor. The compensation circuit includes a preamplifier circuit, a phase shift circuit, and a compensation current generation circuit and also includes a secondary amplification circuit, a filter circuit, a microcontroller, and a digital potentiometer. The microcontroller is configured to control the magnitude of the compensation current by controlling the resistance value of the digital potentiometer. This achieves a wide measurement bandwidth, reduces the error, and improves the measurement accuracy.

FIG. 4 is a flowchart of a control method of a current sensor according to an embodiment of the present disclosure. This embodiment of the present disclosure is applicable to the control of the current sensor. This method can be executed by the current sensor. The current sensor may be implemented by hardware and/or software. The current sensor includes a main core and an auxiliary core; a primary winding disposed on the main core and the auxiliary core; a secondary winding disposed on the main core and the auxiliary core; a compensation winding disposed on the auxiliary core; and a detection winding disposed on the main core.

In the embodiment of the present disclosure, the primary winding is disposed on the main core and the auxiliary core; and the secondary winding disposed on the main core and the auxiliary core. The main core and the auxiliary core are the same in both the magnetic characteristic and the size. In the absence of the compensation winding, the magnetic characteristic of the main core and the magnetic characteristic of the auxiliary core would be identical, and the energy required by the load would be supplied equally by the magnetic winding of the main core and the magnetic winding of the auxiliary core. In the presence of the compensation winding, the compensation winding is configured to generate a compensation current so that the magnetic potential of the auxiliary core is rebalanced, and the energy required by the load is jointly provided by the main core and the auxiliary core, so that the magnetic operating points in the cores change. The detection winding is disposed on the main core and configured to measure the magnetic flux density in the auxiliary core. The magnitude of the induced potential reflects the magnitude of the excitation current. The detection winding is also configured to provide a feedback voltage signal for the compensation winding.

As shown in FIG. 4, the control method includes S110.

In S110, an alternating current (AC) signal induced by the detection winding is acquired, and a current signal is applied to the compensation winding based on the AC signal to make the compensation winding generate a reverse excitation electromotive force to reduce an excitation current in the current sensor.

The compensation circuit determines the magnetic flux in the core by acquiring the voltage signal induced by the detection winding and applies a current signal to the compensation winding to make the compensation winding generate a reverse excitation electromotive force using the compensation winding, thereby reducing the excitation current in the current sensor to a very low level, achieving a wide measurement bandwidth, reducing the margin of error, and improving the measurement accuracy.

According to the solution of this embodiment of the present disclosure, in the control method of the current sensor, the compensation circuit determines the magnetic flux in the core by acquiring the voltage signal induced by the detection winding and applies a current signal to the compensation winding to make the compensation winding generate a reverse excitation electromotive force using the compensation winding, thereby reducing the excitation current in the current sensor to a very low level, achieving a wide measurement bandwidth, reducing the margin of error, and improving the measurement accuracy.

Based on the solution of the previous embodiment of the present disclosure, the current sensor also includes a compensation circuit. The compensation circuit includes a preamplifier circuit, a phase shift circuit, and a compensation current generation circuit. The input of the preamplifier circuit is connected to the detection winding. The input of the phase shift circuit is connected to the output of the preamplifier circuit. The compensation current generation circuit is connected to the output of the phase shift circuit and connected to the compensation winding. The preamplifier circuit is configured to perform preamplification of the induced AC signal. The phase shift circuit is configured to perform phase-shifting processing on an amplified voltage signal and send the phase-shifted amplified voltage signal to the compensation current generation circuit. The compensation current generation circuit is configured to generate a compensation current and output the compensation current to the compensation winding to make the compensation winding generate the reverse excitation electromotive force. The compensation circuit also includes a secondary amplification circuit, a filter circuit, a microcontroller, and a digital potentiometer. The input of the secondary amplification circuit is connected to the output of the preamplifier circuit. The input of the filter circuit is connected to the output of the secondary amplification circuit. The microcontroller is connected to the output of the filter circuit. The digital potentiometer is connected between the microcontroller and the compensation current generation circuit.

In the embodiment of the present disclosure, the preamplifier circuit is configured to amplify the AC signal induced by the detection winding in the main core. The amplified AC signal is processed by the phase shift circuit and then sent to the compensation current generation circuit. Before the amplified AC signal enters the phase shift circuit, the microcontroller detects the magnitude of the voltage signal and uses the data processing capability of the microcontroller to control the digital potentiometer in real time, thereby controlling the compensation current.

The control method includes that the microcontroller controls the magnitude of the compensation current by controlling the resistance value of the digital potentiometer.

In the embodiment of the present disclosure, the microcontroller controls the magnitude of the compensation current by controlling the resistance value of the digital potentiometer. For example, when a larger compensation current is required, the microcontroller adjusts the resistance value of the digital potentiometer to reduce the resistance value of the digital potentiometer, thereby increasing the compensation current.

The current sensor of this embodiment of the present disclosure can perform the control method of the current sensor of any embodiment of the present disclosure and has function modules and beneficial effects corresponding to the performed method.

It is to be understood that various forms of the preceding flows may be used with steps reordered, added, or deleted. For example, the steps described in the present disclosure may be performed in parallel, in sequence, or in a different order as long as the desired result of the technical solutions provided in the present disclosure can be achieved. The execution sequence of these steps is not limited herein.

The scope of the present disclosure is not limited to the preceding embodiments. It is to be understood by those skilled in the art that various modifications, combinations, subcombinations and substitutions may be made according to design requirements and other factors. Any modification, equivalent substitution, or improvement made within the spirit and principle of the present disclosure fall within the scope of the present disclosure.

What is claimed is:

1. A current sensor, comprising:
a main core and an auxiliary core;
a primary winding disposed on the main core and the auxiliary core;
a secondary winding disposed on the main core and the auxiliary core;
a compensation winding disposed on the auxiliary core;
a detection winding disposed on the main core; and
a compensation circuit configured to acquire an alternating current (AC) signal induced by the detection winding and apply a current signal to the compensation winding based on the AC signal to make the compensation winding generate a reverse excitation electromotive force to reduce an excitation current in the current sensor.

2. The current sensor of claim 1, wherein the primary winding passes through a middle of the main core and a middle of the auxiliary core in a through-core connection, and the secondary winding is wound around the main core and the auxiliary core.

3. The current sensor of claim 1, wherein the compensation circuit is configured to reduce the excitation current to less than a preset value.

4. The current sensor of claim 1, wherein
a magnitude of an induced potential in the compensation winding reflects a magnitude of the excitation current; and
the compensation circuit is configured to determine a magnetic flux in the main core based on a magnitude of a voltage signal of the compensation winding to control a magnitude of an output compensation current.

5. The current sensor of claim 1, wherein
the compensation circuit comprises a preamplifier circuit, a phase shift circuit, and a compensation current generation circuit;
an input of the preamplifier circuit is connected to the detection winding, an input of the phase shift circuit is connected to an output of the preamplifier circuit, and the compensation current generation circuit is connected to an output of the phase shift circuit and connected to the compensation winding;
the preamplifier circuit is configured to perform preamplification of the induced AC signal;
the phase shift circuit is configured to perform phase-shifting processing on the AC signal and send the phase-shifted amplified AC signal to the compensation current generation circuit; and
the compensation current generation circuit is configured to generate a compensation current and output the compensation current to the compensation winding to make the compensation winding generate the reverse excitation electromotive force.

6. The current sensor of claim 5, wherein
the compensation circuit further comprises a secondary amplification circuit, a filter circuit, a microcontroller, and a digital potentiometer;
an input of the secondary amplification circuit is connected to the output of the preamplifier circuit;
an input of the filter circuit is connected to an output of the secondary amplification circuit;
the microcontroller is connected to an output of the filter circuit, and the digital potentiometer is connected between the microcontroller and the compensation current generation circuit; and
the microcontroller is configured to control a magnitude of the compensation current by controlling a resistance value of the digital potentiometer.

7. The current sensor of claim 5, further comprising a first clipping protection circuit and a second clipping protection circuit, wherein
the first clipping protection circuit is connected between the detection winding and the preamplifier circuit; and
the second clipping protection circuit is connected between the compensation current generation circuit and the compensation winding; and the first clipping protection circuit and the second clipping protection circuit are configured for current surge protection.

8. The current sensor of claim 1, further comprising a secondary load connected to the secondary winding, wherein energy required by the secondary load is supplied by the auxiliary core, and zero magnetic flux is reached in the main core.

9. A control method of a current sensor, wherein
the current sensor comprises a main core and an auxiliary core; a primary winding disposed on the main core and the auxiliary core; a secondary winding disposed on the main core and the auxiliary core; a compensation winding disposed on the auxiliary core; and a detection winding disposed on the main core; and
the control method comprises acquiring an alternating current (AC) signal induced by the detection winding and applying a current signal to the compensation winding based on the AC signal to make the compensation winding generate a reverse excitation electromotive force to reduce an excitation current in the current sensor.

10. The method of claim 9, wherein
the current sensor further comprises a compensation circuit, and the compensation circuit comprises a preamplifier circuit, a phase shift circuit, and a compensation current generation circuit;
an input of the preamplifier circuit is connected to the detection winding, an input of the phase shift circuit is connected to an output of the preamplifier circuit, and the compensation current generation circuit is connected to an output of the phase shift circuit and connected to the compensation winding;
the preamplifier circuit is configured to perform preamplification of the induced AC signal;
the phase shift circuit is configured to perform phase-shifting processing on the AC signal and send the phase-shifted amplified AC signal to the compensation current generation circuit;
the compensation current generation circuit is configured to generate a compensation current and output the compensation current to the compensation winding to make the compensation winding generate the reverse excitation electromotive force;
the compensation circuit further comprises a secondary amplification circuit, a filter circuit, a microcontroller, and a digital potentiometer;
an input of the secondary amplification circuit is connected to the output of the preamplifier circuit;
an input of the filter circuit is connected to an output of the secondary amplification circuit;
the microcontroller is connected to an output of the filter circuit, and the digital potentiometer is connected between the microcontroller and the compensation current generation circuit; and
the control method comprises controlling, by the microcontroller, a magnitude of the compensation current by controlling a resistance value of the digital potentiometer.
